(19) United States
(12) Patent Application Publication
(10) Pub. No.: US 2010/0109667 A1
(43) Pub. Date: May 6, 2010

(54) TRANSVERSE ELECTROMAGNETIC RADIO-FREQUENCY COIL

(75) Inventor: Christoph Leussler, Hamburg (DE)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., EINDHOVEN (NL)

(21) Appl. No.: 12/598,447

(22) PCT Filed: May 5, 2008
(86) PCT No.: PCT/IB08/51730

§ 371 Date: Nov. 2, 2009

(30) Foreign Application Priority Data
May 3, 2007 (EP) 07107397.7

(51) Int. Cl. G01R 33/44

(52) U.S. Cl. 324/318

(57) ABSTRACT

A transverse-electromagnetic (TEM) radio-frequency(RF) coil array (100) for examining a subject in a magnetic resonance system is disclosed, wherein the TEM RF coil array comprises two or more parallel loop elements (101a, 102a) configured to transmit RF signals independently to the subject (103). The two or more parallel loop elements are arranged to intersect at a point at one end of the loop elements, thereby forming a cylindrical coil array closed at one end and open at the other.

### FIELD OF THE INVENTION

The invention relates to the field of magnetic resonance (MR), particularly to transverse-electromagnetic (TEM) radio-frequency (RF) coils used in MR applications.

### BACKGROUND OF THE INVENTION

The U.S. Pat. No. 7,023,209 B2 discusses various embodiments of an MRI coil formed from microstrip transmission lines. The coil's distributed element design provides for operation at relatively high quality factors and frequencies and in high fields (4 Tesla or more) environments. Further, the microstrip coils exhibit low radiation losses and require no RF shielding, as a result of which, the coils may be of compact size while having high operating frequencies for high-field MR studies, thus saving space in the MRI machine. In an example embodiment, the microstrip coil is formed as a dome-shaped coil which offers an increased filling factor and a greater sensitivity and homogeneity in the top area of the human head. By applying the microstrip resonator volume coil technique, the dome-shaped coil can be constructed for higher field applications.

### SUMMARY OF THE INVENTION

In the prior art, though the dome-shaped RF coil has good sensitivity and homogeneity for receiving MR signals from the top area of a human head, the electromagnetic (EM) coupling between the main magnetic field and the RF coil makes it difficult to obtain good estimates of local specific absorption rate (SAR) and B₁ sensitivity maps, especially when such a coil is used to transmit RF signals at higher field strengths. In other words, it is difficult to obtain predictable and reproducible EM transmit-field patterns for such a coil, especially at high field strengths. It is thus desirable to have an RF coil or an RF coil array that combines the high sensitivity and homogeneity of a dome-shaped receive-coil array with the advantage of predictable and reproducible EM transmit-field patterns.

Accordingly, a TEM RF coil array for examining a subject in an MR system is proposed, wherein the TEM RF coil array comprises two or more parallel loop elements configured to transmit RF signals independently to the subject. The two or more parallel loop elements are arranged to intersect at a point at one end of the loop elements, thereby forming a cylindrical coil array closed at one end and open at the other.

By having a coil array in which each loop element is capable of independently transmitting an RF signal, it is possible to produce a predictable and reproducible EM transmit-field pattern by controlling the shapes, amplitudes and phases of the individual RF pulses being transmitted independently by the various loop elements. The “closed” portion of the coil array improves the filling-factor and homogeneity for receiving signals from extremities such as the human head or limbs. Furthermore, the “closed” shape helps to minimize radiation losses, making the coil array usable at high-field and ultra-high-field strengths.

### BRIEF DESCRIPTION OF THE DRAWINGS

These and other aspects will be described in detail hereinafter, by way of example, on the basis of the following embodiments, with reference to the accompanying drawings, wherein:

FIG. 1 shows a cylindrical TEM RF coil array closed at one end and open at the other;

FIG. 2 shows the cylindrical TEM RF coil array, including a cylindrical RF shield;

FIG. 3 shows the cylindrical TEM RF coil array including the shield, wherein the shield is shaped to conform to the shape of the radio-frequency coil array;

FIGS. 4a and 4b show transverse cross-sectional views of two embodiments of the TEM RF coil array as disclosed herein;

FIG. 5 shows a transverse cross-sectional view of an embodiment of the TEM RF coil array, including multiple local shields per loop element;

FIG. 6 shows a segmented version of the TEM RF coil array, wherein each loop element is segmented into multiple conducting strips with an overlap between adjacent conducting loop elements along the length of the loop element;

FIGS. 7a and 7b show different ways in which capacitances can be formed along the length of a loop element of the TEM RF coil array;

FIGS. 8a and 8b illustrate shielding of the reactive coupling elements (e.g., capacitors) of a microstrip line forming a loop element;

FIGS. 9a and 9b schematically show the TEM RF coil array, including a microstrip line for the RF shield;

FIG. 10 shows an embodiment of the TEM RF coil array optimized for head and neck imaging; and

FIG. 11 shows an MR system capable of utilizing the TEM RF coil array disclosed herein.

Corresponding reference numerals when used in the various figures represent corresponding elements in the figures.

### DETAILED DESCRIPTION OF EMBODIMENTS

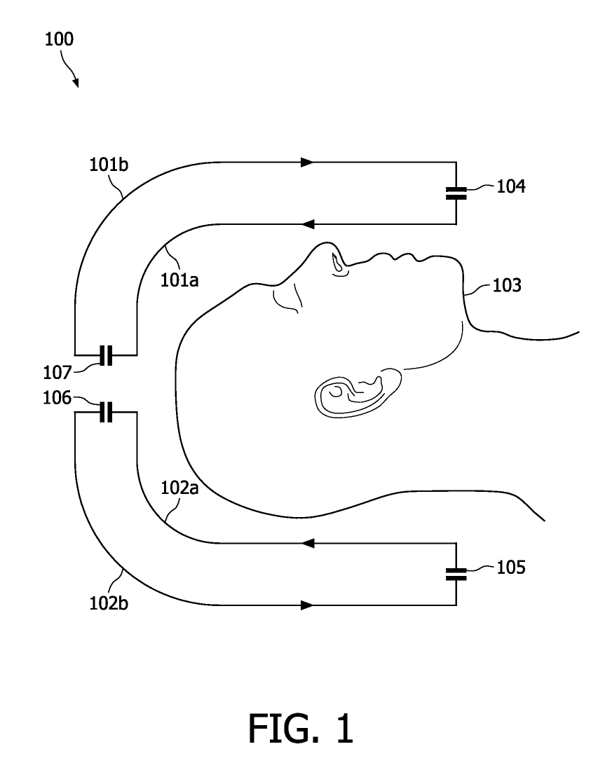

FIG. 1 shows an embodiment of the TEM RF coil, wherein a TEM RF coil 100 is formed from multiple loop elements such as 101a and 102a. Each loop element 101a, 102a provides the current-forward path, while the current-return path is provided by a corresponding return electrical line 101b and 102b, respectively. The resonance frequency of the TEM RF coil is determined by the values of capacitors 104, 105, 106 and 107. If the capacitor values are chosen appropriately, they can also serve to reduce/prevent eddy currents on the loop elements. Examples of appropriate capacitor values are around 1 to 10 nF. The loop elements 101a, 102a bend towards each other and intersect at a point, thereby forming a cylindrical shape that is closed at one end and open at the other.

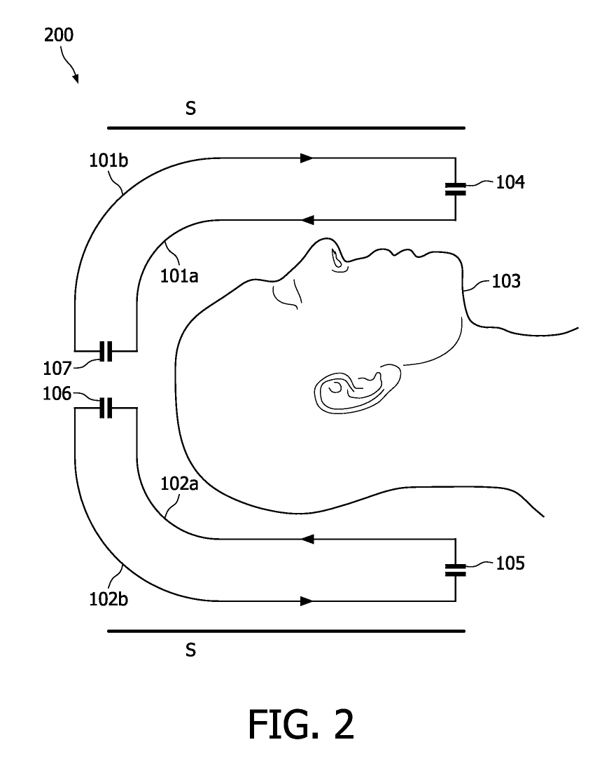

FIG. 2 shows an embodiment of the TEM RF coil 200, including a shield S. The shield extends around the circumference of the coil and minimizes interactions of the RF coil with the main magnetic field or with stray RF fields.

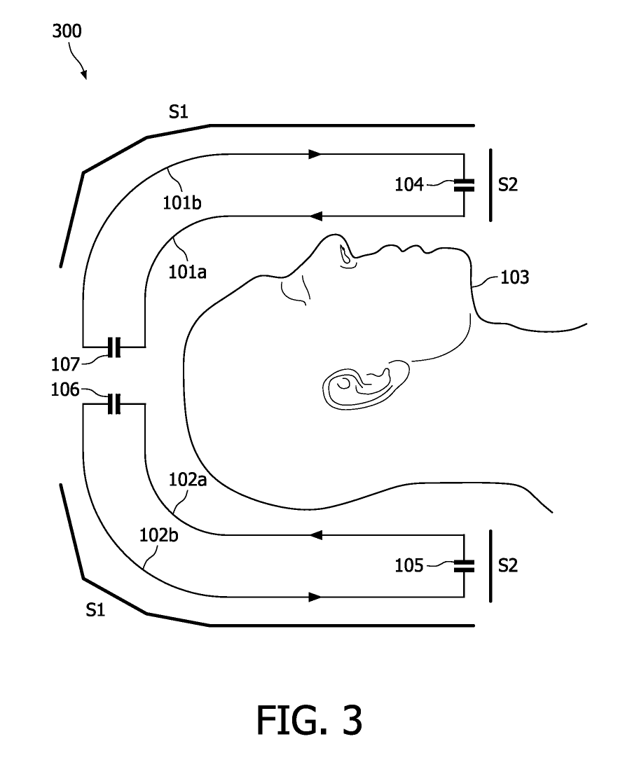

FIG. 3 shows an embodiment of the TEM RF coil 300, wherein a shield S1 is contoured to follow the shape of the coil. Additionally, a portion of the shield S2 helps to minimize signal from tissue in the neck and shoulders of the subject 103.

To enable independent control of each of the loop elements, each loop element 101a, 102a is connected to its own transmit/receive channel (not shown). Such a system wherein each loop element of an RF coil is connected to its own transmit channel is called a multi-transmit system. It may be noted that all the embodiments disclosed in this application apply to multi-transmit RF coil systems.

A “TEM resonator” is typically a coil circuit that incorporates flat or coaxial transmission line elements or stripline or microstrip elements, and resonant cavities or waveguides in their design, operating in a TEM mode. In general, TEM coils have low radiation losses and are useful for operation at higher frequencies. Additional information about TEM coils may be obtained from the U.S. Pat. No. 746,866, “High-frequency coil system for a magnetic resonance imaging apparatus”, awarded to Roschmann P. K. in 1988.

In the various figures discussed above, only 2 loop elements are shown, for the sake of clarity. It is, however, to be understood that this concept may be extended to coils with more loop elements, e.g., 4, 8, 12, 20, etc. A larger number of loop elements will give better control over shaping the transmit-field pattern. For each loop element 101a, 102a, the current-return path 101b, 102b can be made from a normal wire or from a microstrip line that is wider than the corresponding loop element. This helps the current return path 101b, 102b to also act as RF shields for the corresponding loop elements 101a, 102a, respectively.

It is conceivable that at the point of intersection, the various loop elements could couple to each other inductively due to their proximity to one another. Such inductive coupling can however be minimized, i.e., some amount of decoupling can be achieved, by overlapping the loop elements at the point of intersection.

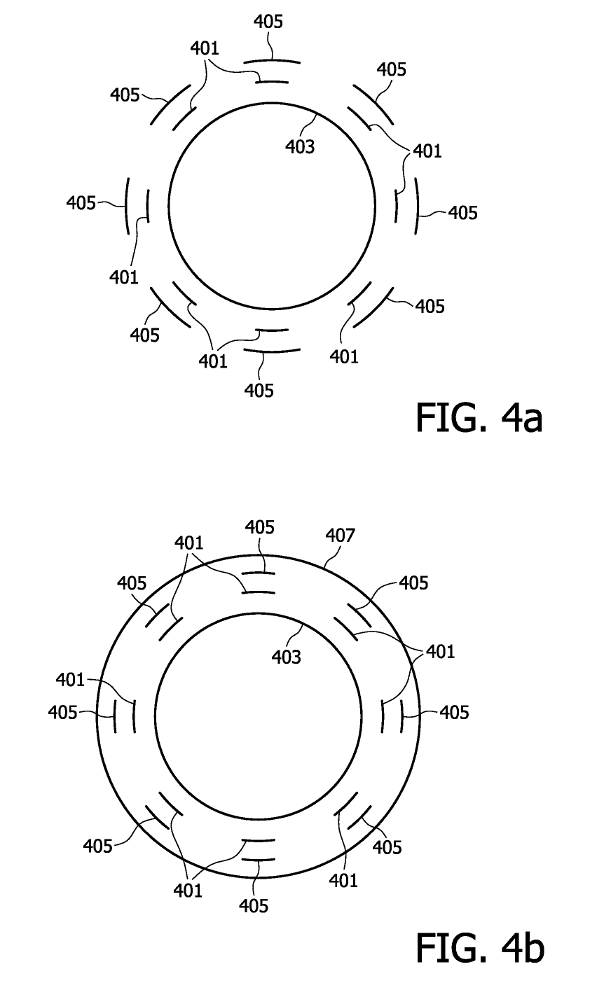

FIGS. 4a and 4b show a transverse cross-sectional view of the TEM RF coil array disclosed herein. In FIG. 4a, the individual microstrip lengths forming the loop elements 401 provide the forward current path. Each loop element 401 has an associated local shield 405 that, in addition to shielding the associated loop element 401 from stray RF fields, also provides the return current path. In FIG. 4b, in addition to the local shield 405, an additional shield 407 is provided for enhanced shielding from stray RF fields. In this embodiment also, the local shield 405 provides the return current path for the loop elements 401. The subject under examination is shown by the innermost circle 403.

It is to be noted that in place of the associated local shield 405 for each loop element 401 in FIG. 4a, it is possible to have a cylindrical shield similar to the additional shield 407 in FIG. 4b that provides the current return path. In other words, the local shields 405 may be connected together to provide a common current return path for all of the individual loop elements 401.

During operation at very high frequencies, such as in high-field and ultra-high field MRI applications, the local shield alone may not provide sufficient shielding, especially in cases where a gradient coil is located in close proximity to the TEM RF coil. Under such conditions, the additional shield 407 shown in FIG. 4b provides the required additional isolation.

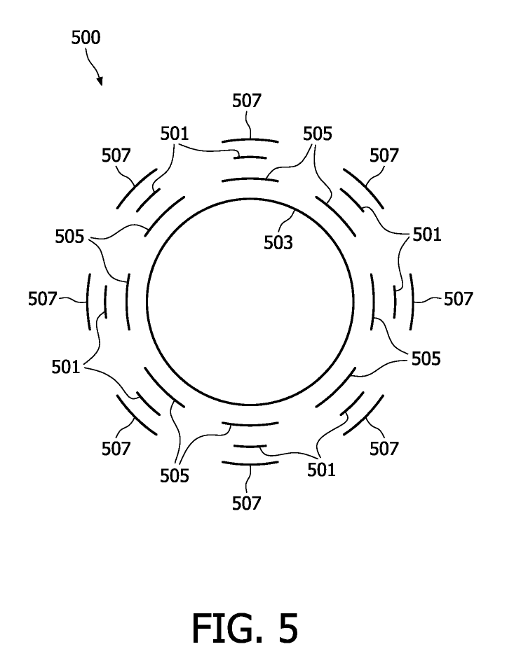

FIG. 5 shows a transverse cross-section of an embodiment of the TEM RF coil 500 that includes an inner local shield 505 and an outer local shield 507 placed on either side of the loop element 501. The inner local shield 505 reduces electrical fields that the subject 503 may otherwise be exposed to. Either the inner or the outer local shield 505, 507 may provide the return current path. Alternatively, both the inner and outer local shields 505, 507 may be connected together to provide a single return current path.

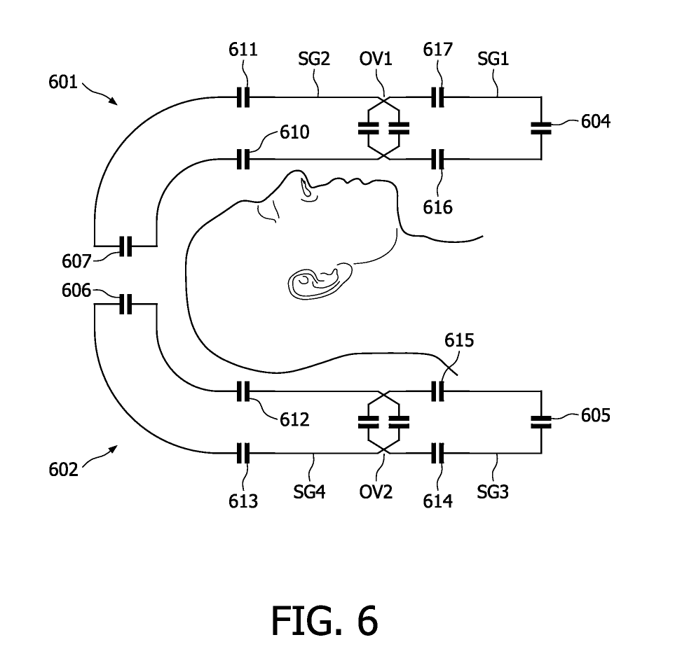

FIG. 6 shows an embodiment of the TEM RF coil wherein the loop elements 601, 602 are composed of segments SG1, SG2 and SG3, SG4, respectively. The overlapping section OV1 serves to minimize the inductive coupling between the segments SG1 and SG2 of loop element 601. Similarly, the overlapping section OV2 serves to decouple the segments SG3 and SG4 of loop element 602. The capacitors 604, 605, 606 and 607, together with the additional capacitors 610, 611, 612, 613, 614, 615, 616 and 617 make the (respective) individual TEM RF coil element SG1, SG2, SG3 and SG4 resonant, and reduce electromagnetic propagation, thus increasing self-resonance and reducing electric fields.

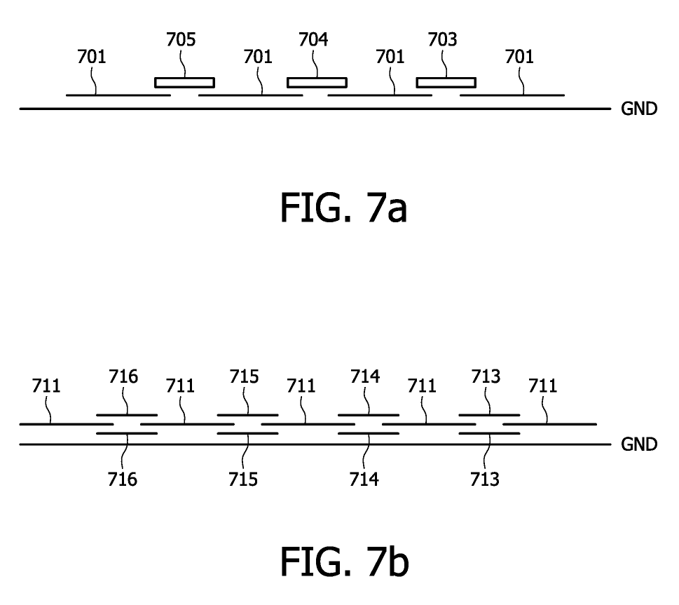

The distribution of capacitors along the length of a loop element is shown in FIGS. 7a and 7b. FIG. 7a shows a length of microstrip cable forming a loop element 701 of the TEM RF coil, with lumped-element discrete capacitors 703, 704 and 705 distributed along the length of the loop element 701. The capacitors are shown separated from the microstrip lines 701 for purposes of illustration alone; in fact, they are connected along the length of the microstrip element to form the complete loop element 701. FIG. 7B shows an embodiment of the TEM RF coil in which the microstrip loop element 711 has distributed lumped-element capacitors 713, 714, 715 and 716, each of which has been formed by sandwiching dielectric material between multiple conducting layers, using multi-layer technology.

In general, a common single discrete ceramic capacitor consists of a dielectric layer sandwiched between conductive layers. This capacitor has to be soldered or connected between the conductors or microstrip. Instead of using discrete ceramic capacitors, the capacitor can be formed or incorporated into the microstrip by using local additional dielectric and conductive layers between the microstrip using common multilayer low-loss PCB material. Capacitors can be formed and integrated by the microstrip material itself so that production of the coil array is more efficient.

Distribution of the capacitors along the length of the loop element provides a homogeneous RF current distribution. Additionally, by using different capacitance values, the current distribution can be controlled, thus enabling controlled generation of B₁ gradients (i.e., RF fields generated by the TEM RF coil array). This can be of advantage especially for static or RF shimming of the B₁ field with the subject positioned for examination in an MR system. Furthermore, the use of different lumped capacitance elements or capacitors in different loop elements permits different loop elements to be tuned to different frequencies, thus providing for a multiple-tuned TEM RF coil array that is capable of transmitting simultaneously at multiple frequencies.

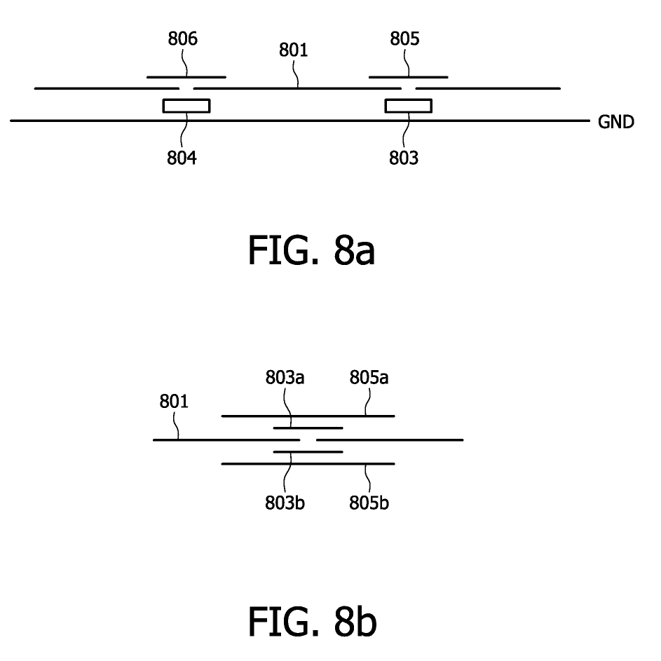

FIGS. 8a and 8b show examples of shielding the distributed capacitors used in a loop element of the TEM RF coil array disclosed herein. Local flat shields 805, 806 prevent stray electrical fields caused by the high local electric fields present close to the lumped element discrete capacitors 803, 804 from radiating into the environment. Local shielding can be provided on either one side of the loop element 801 as shown in FIG. 8a or on both sides as shown in FIG. 8b. The capacitor is formed by sandwiching a dielectric layer between two conducting layers 803a, 803b as shown in FIG. 8b, using multi-layer technology. A flat copper shield 805a, 805b is integrated into the multiple layers and forms the top (or outermost) layer of the multiple layers. The shield may be grounded to the outer ground GND by ordinary wires or microstrip elements.

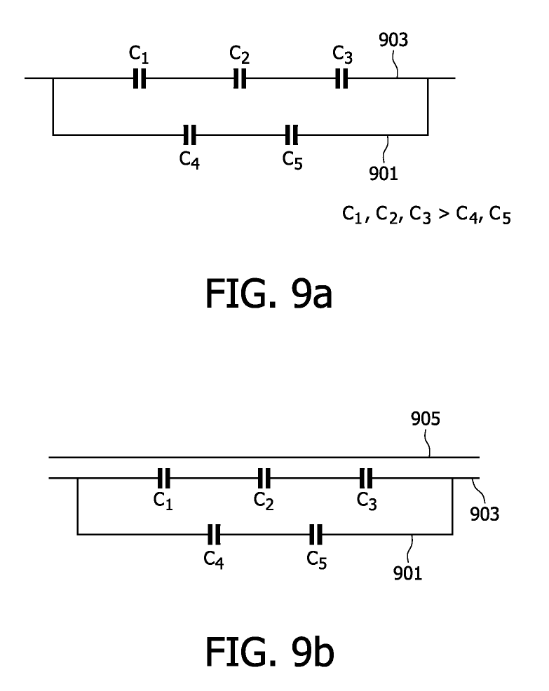

FIGS. 9a and 9b schematically show embodiments of the TEM RF coil array in which both the loop elements as well as the RF shields are made from microstrip cables. In general, the capacitance values of the capacitors C4, C5 incorporated into the loop element or microstrip 901 are smaller than that of the capacitors C1, C2, C3 incorporated into the shield 903. In additional to providing a shielding function, the local shield 903 also provides a current return path.

The capacitors C1, C2 and C3 located in the shield 903 serve to prevent or minimize eddy currents that may arise in the shields due to their proximity to the gradient coils of an MR system, when the gradient coils are in operation. The capacitors C1, C2 and C3 also serve to reduce the electric field over the current return shield, as otherwise the inductivity of this shield may be too high and wave propagation effects may be reduced. An additional outer shield 905 may also be provided to further minimize eddy current formation due to interaction between the local shield 903 and a nearby gradient coil.

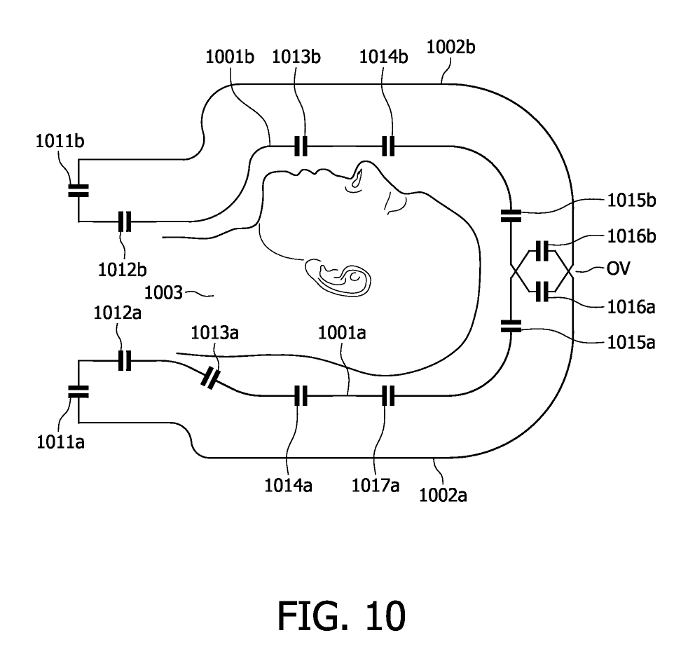

FIG. 10 shows a specific embodiment of the TEM RF coil array disclosed herein that is tailored for MR examination of the human head and neck. The loop elements 1001a, 1001b of the coil intersect at a point near the top of the head of the subject 1003 and overlap one another as shown by the section OV, to achieve some decoupling between the various loop elements. Additionally, the coil also bends at the bottom of the head, i.e., near the neck region, in order to provide homogenous field distribution all over the head region. The capacitors 1011a, 1012a, 1013a, 1014a, 1015a, 1016a and 1017a for loop element 1001a, and 1011b, 1012b, 1013b, 1014b, 1015b and 1016b for loop element 1001b serve to capacitively couple the various microstrip lines to form the complete loop element 1001a and 1001b, respectively. The capacitors also determine the resonant frequency of the RF coil for operation at the particular field strength of an MR system. The number of capacitive elements in the various loop lines need not be equal and could be different based on need. For example, in the figure, the loop element 1001a contains an extra length of microstrip line, necessitating the use of an additional capacitor 1017a.

It may be noted that microstrip cables may also be used for the current return paths 1002a (for loop element 1001a) and 1002b (for loop element 1002b), similar to the embodiments discussed with reference to FIGS. 9a and 9b. Furthermore, additional shielding may also be provided, as discussed earlier with reference to FIG. 4b.

In the embodiments discussed above, microstrip lines (otherwise known as Safe Transmission Lines or STL) are used, for example, to construct the coil elements. Although only examples of capacitively coupled microstrip lines have been shown, it is conceivable to use inductively coupled microstrip lines to construct the TEM RF coil instead. To cover both inductively-coupled and capacitively-coupled microstrip lines, the terms “reactively-coupled”, “reactive coupling” etc., have been used in this document.

Advantages of such a construction (i.e., reactively-coupled microstrip lines) include a constant RF current distribution and higher B₁ sensitivity, reduction of RF propagation effects and reduced dielectric losses in tissue. The distributed capacitors shown in the various embodiments may be discrete chip capacitors or distributed capacitors made by overlapping appropriate portions of the printer circuit board. The shape of the microstrip may be changed over its length or its height over ground, which changes the effective magnetic field sensitivity and modulates the RF field. The local and additional shields provided over the capacitors in the microstrip line reduce local stray EM fields and thus help to reduce SAR in tissue. In place of microstrip lines, it is conceivable to use other type of transmission elements in order to construct the TEM RF coil disclosed herein, as long as they are safe for operation in an MR environment.

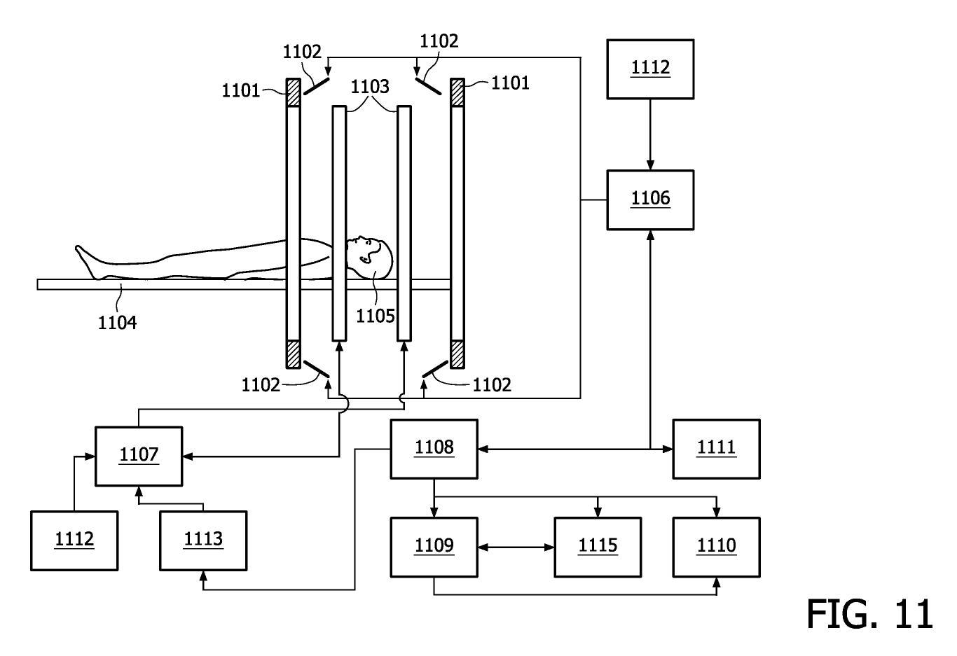

FIG. 11 shows a possible embodiment of an MR system utilizing the TEM RF coil array as disclosed herein. The MR system comprises a set of main coils 1101, multiple gradient coils 1102 connected to a gradient driver unit 1106, and RF coils 1103 connected to an RF coil driver unit 1107. The function of the RF coils 1103, which may be integrated into the magnet in the form of a body coil, or may be separate coils, is further controlled by a transmit/receive (T/R) switch 1113. The multiple gradient coils 1102 and the RF coils 1103 are powered by a power supply unit 1112. A transport system 1104, for example a patient table, is used to position a subject 1105, for example a patient, within the MR imaging system. A control unit 1108 controls the RF coils 1103 and the gradient coils 1102. The control unit 1108, though shown as a single unit, may be implemented as multiple units as well. The control unit 1108 further controls the operation of a reconstruction unit 1109. The control unit 1108 also controls a display unit 1110, for example a monitor screen or a projector, a data storage unit 1115, and a user input interface unit 1111, for example, a keyboard, a mouse, a trackball, etc.

The main coils 1101 generate a steady and uniform static magnetic field, for example, of field strength 3T, 4.7T or 9.4T. The disclosed TEM RF coil may be employed at other field strengths as well, including lower field strengths like 1T, 1.5T, etc. The main coils 1101 are arranged in such a way that they typically enclose a tunnel-shaped examination space, into which the subject 1105 may be introduced. Another common configuration comprises opposing pole faces with an air gap in between them into which the subject 1105 may be introduced by using the transport system 1104. To enable MR imaging, temporally variable magnetic field gradients superimposed on the static magnetic field are generated by the multiple gradient coils 1102 in response to currents supplied by the gradient driver unit 1106. The power supply unit 1112, fitted with electronic gradient amplification circuits, supplies currents to the multiple gradient coils 1102, as a result of which gradient pulses (also called gradient pulse waveforms) are generated. The control unit 1108 controls the characteristics of the currents, notably their strengths, durations and directions, flowing through the gradient coils to create the appropriate gradient waveforms. The RF coils 1103 generate RF excitation pulses in the subject 1105 and receive MR signals generated by the subject 1105 in response to the RF excitation pulses. The RF coil driver unit 1107 supplies current to the RF coil 1103 to transmit the RF excitation pulses, and amplifies the MR signals received by the RF coil 1103. The transmitting and receiving functions of the RF coil 1103 or set of RF coils are controlled by the control unit 1108 via the T/R switch 1113. The T/R switch 1113 is provided with electronic circuitry that switches the RF coil 1103 between transmit and receive modes, and protects the RF coil 1103 and other associated electronic circuitry against breakthrough or other overloads, etc. The characteristics of the transmitted RF excitation pulses, notably their strength and duration, are controlled by the control unit 1108.

It is to be noted that though the transmitting and receiving coil are shown as one unit in this embodiment, it is also possible to have separate coils for transmission and reception, respectively. It is further possible to have multiple RF coils 1103 for transmitting or receiving or both. The RF coils 1103 may be integrated into the magnet in the form of a body coil, or may be separate coils. They may have different geometries, for example, a birdcage configuration or a simple multi-loop configuration, etc. The control unit 1108 is preferably in the form of a computer that includes a processor, for example a microprocessor. The control unit 1108 controls, via the T/R switch 1113, the application of RF pulse excitations and the reception of MR signals comprising echoes, free induction decays, etc. User input interface devices 1111 like a keyboard, mouse, touch-sensitive screen, trackball, etc., enable an operator to interact with the MR system.

The MR signal received with the RF coils 1103 contains the actual information concerning the local spin densities in a region of interest of the subject 1105 being imaged. The received signals are reconstructed by the reconstruction unit 1109, and displayed on the display unit 1110 as an MR image or an MR spectrum. It is alternatively possible to store the signal from the reconstruction unit 1109 in a storage unit 1115, while awaiting further processing. The reconstruction unit 1109 is constructed advantageously as a digital image-processing unit that is programmed to derive the MR signals received from the RF coils 1103.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A transverse-electromagnetic radio-frequency coil array for examining a subject in a magnetic resonance system, comprising:
two or more parallel loop elements configured to transmit radio-frequency signals independently to the subject, wherein the two or more parallel coil elements are arranged to intersect at a point at one end of the loop elements, thereby forming a cylindrical coil array closed at one end and open at the other.

2. The radio-frequency coil array of claim 1, including a cylindrical radio-frequency shield located outside of and concentric to the cylindrical radio-frequency coil array.

3. The radio-frequency coil array of claim 2, wherein the radio-frequency shield is contoured to conform to the shape of the radio-frequency coil array, thereby forming a cylindrical shield that is closed at one end and open at the other.

4. The radio-frequency coil array of claim 1, wherein the parallel loop elements are formed from microstrip cable lengths connected together by distributed lumped-element reactive coupling elements.

5. The radio-frequency coil array of claim 1, wherein each parallel loop element is segmented along its length, each segment being reactively coupled to its adjacent segments by reactive coupling elements, thereby forming the loop element.

6. The radio-frequency coil array of claim 1, wherein each parallel loop element is individually shielded.

7. The radio-frequency coil array of claim 1, wherein the two or more parallel loop elements are configured to overlap at the closed end in order to mutually decouple the loop elements.

8. The radio-frequency coil array of claim 1, including a circular flange shield at the open end of the radio-frequency coil array, thereby limiting interaction of the radio-frequency coil array to an anatomical region of interest.

9. The radio-frequency coil array of claim 1, wherein the cross-sectional diameter of the radio-frequency coil changes along a long axis of the coil array parallel to the loop elements, based on the change in size of the subject's anatomy along the long axis of the coil array.

10. The radio-frequency coil of claim 4, wherein each reactive coupling element is individually shielded to minimize interaction with stray radio-frequency fields.

11. A magnetic resonance system including a transverse-electromagnetic radio-frequency coil array for examining a subject in the magnetic resonance system, the transverse-electromagnetic radio-frequency coil array comprising:
two or more parallel loop elements configured to transmit radio-frequency signals independently to the subject, wherein the two or more parallel coil elements are arranged to intersect at a point at one end of the loop elements, thereby forming a cylindrical coil array closed at one end and open at the other.
